(19) United States
(12) Patent Application Publication
(10) Pub. No.: US 2023/0313367 A1
(43) Pub. Date: Oct. 5, 2023

(54) METHODS AND APPARATUS FOR CHAMBER LID COOLING

(71) Applicant: ASM IP Holding B.V., Almere (NL)

(72) Inventors: Ankit Kimtee, Phoenix, AZ (US); Akshay Phadnis, Phoenix, AZ (US); Kyle Fondurulia, Phoenix, AZ (US); Thomas Fitzgerald, Gilbert, AZ (US)

(21) Appl. No.: 18/127,785

(22) Filed: Mar. 29, 2023

Related U.S. Application Data
(60) Provisional application No. 63/326,348, filed on Apr. 1, 2022.

(51) Int. Cl. C23C 16/44; C23C 16/455

(52) U.S. Cl. CPC C23C 16/4411; C23C 16/45565; C23C 16/45544

(57) ABSTRACT

A reactor system for use in semiconductor processing, such as for chemical vapor deposition (CVD), atomic layer deposition (ALD), and other deposition steps, that makes use of a reactor module with two or more reaction chambers. The reactor system includes components of a cooling system to provide enhanced temperature uniformity across a chamber lid enclosing the housing or vessel containing the reaction chambers. In part, the cooling system is adapted to utilize convective heat transfer and includes a finned heat sink positioned at the center of the chamber lid in the center space between the external portions of the showerheads of the reaction chambers. Further, the cooling system includes a fan positioned to have its outlet at the center space and over the finned heat sink so that air is directed into the center space and onto the heat sink.

### CROSS-REFERENCE TO RELATED APPLICATIONS

This application is a nonprovisional of, and claims priority to and the benefit of, U.S. Provisional Patent Application No. 63/326,348, filed Apr. 1, 2022 and entitled “METHODS AND APPARATUS FOR CHAMBER LID COOLING,” which is hereby incorporated by reference herein.

### FIELD OF THE DISCLOSURE

The present disclosure relates generally to methods and systems for controlling temperatures of interior spaces of reaction chambers in a semiconductor processing or reactor system during deposition on wafers, and, more particularly, to a method and an apparatus for controlling temperatures of a chamber lid of a reaction chamber module containing two or more reaction chambers to maintain temperature uniformity within the reaction chambers or internal processing spaces.

### BACKGROUND OF THE DISCLOSURE

Semiconductor processing, including chemical vapor deposition (CVD), atomic layer deposition (ALD), and the like, is commonly used for forming thin films of materials on substrates, such as silicon wafers. In a CVD process, for example, gaseous molecules of the material to be deposited are supplied to substrates to form a thin film of that material on the substrates by chemical reaction. Such formed thin films may be polycrystalline, amorphous, or epitaxial. Typically, CVD processes are conducted at elevated temperatures to accelerate the chemical reaction and to produce high quality films, and deposition materials (e.g., precursors, reactants, and the like) may be provided to a reaction chamber via a showerhead or the like via a liquid source that is maintained at temperatures within a carefully monitored and often relatively small temperature control range or band.

There has been an ongoing effort in the semiconductor industry to increase the efficiency of semiconductor processing while lowering or controlling costs and space requirements. This has resulted in semiconductor processing systems or tools that include reaction chamber modules with two or more reaction chambers within a single housing or vessel rather than an isolated single chamber design. For example, there are ALD and CVD reactor systems or tools with one or more dual chamber modules and/or with one or more quad chamber modules. In such systems or tools, a single housing or vessel is used to contain two or four reaction chambers. A single or unitary lid may be used to support multiple showerheads and above the reaction chambers.

Providing two or more showerheads and respective reaction chambers within a single housing can lead to design and operational challenges including temperature management. In practice, it is desirable for the chamber lid of each module to have a uniform temperature profile across its surface and over each reaction chamber. In a quad chamber module, for example, all four reaction chambers are thermally connected to each other, and this can produce a center hot spot. The temperature non-uniformity in the top part or lid of the chamber may be reflective on a wafer, which may cause undesirable hot spots and even, in some cases, poor deposition results on the wafer. Hence, there remains a demand for reactor system designs that allow for multi-chamber modules while providing enhanced uniformity of temperatures including on the chamber lid.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein, according to various embodiments, is a reactor system for use in semiconductor processing, such as for chemical vapor deposition (CVD), atomic layer deposition (ALD), and other deposition techniques, that makes use of a reactor module with two to four or more reaction chambers. The reactor system includes components of a cooling system to provide enhanced temperature uniformity across a chamber lid enclosing the housing or vessel containing the reaction chambers. In part, the cooling system is adapted to utilize convective heat transfer and includes a finned heat sink positioned at the center of the chamber lid in the center space between the external portions of the showerheads of the reaction chambers. Further, the cooling system includes a cooling fan positioned to have its outlet at the center space and over the finned heat sink so that air out of (or cooling air) is directed into the center space and onto the heat sink.

In some exemplary embodiments, a reactor system is provided that is adapted for forced convection cooling of a multi-chamber module. The system includes a lid for the multi-chamber module and a set of showerheads supported on the lid. Each of the showerheads includes a body with a sidewall extending a distance outward from an outer surface of the lid. The system further includes a cooling channel including gaps between the sidewalls of adjacent pairs of the showerheads. A fan assembly is provided with a fan housing enclosing an impeller and a motor and defining a fan inlet and a fan outlet. When the motor is operating, cooling air is drawn into the fan inlet from a space exterior to the lid and forced out of the fan outlet into the cooling channel to flow through the gaps.

In some examples of the system, the set of showerheads includes two or more (e.g., four) showerheads, and the cooling channel further includes a center space enclosed by the fan housing, a center portion of the outer surface of the lid, and adjacent portions of the sidewalls of the bodies of the showerheads. The fan outlet is configured to direct the cooling air forced out of the fan outlet into the center space. The system can also include a heat sink positioned within the center space and integrally formed with the lid or in contact with the outer surface of the lid, and the heat sink can include a plurality of fins extending outward away from the lid.

In some cases, the fan assembly has a center axis that coincides with a center of the center space and a center of the lid. The system can also include a set of module hardware extending over and at least partially enclosing the gaps, whereby the cooling air is directed to flow between adjacent pairs of the showerheads. The motor can be a variable speed motor operable over a range of speeds, and the system can further include a controller configured to generate control signals to operate the motor at a first speed and at a second speed higher than the first speed. A temperature sensor may be provided that is adapted to sense a temperature of the lid, and the controller can generate the control signals to switch between the first and second speeds based on the sensed temperature of the lid. In some implementations, the controller generates the control signals to switch between the first and second speeds based on a change in processes performed in the multi-chamber module.

According to other aspects of the description, a method is provided of controlling a chamber lid temperature in a reactor system. The method can include operating a fan at a first speed to direct a flow of cooling air onto an outer surface of the chamber lid and then sensing a temperature of the chamber lid. The method can also include, based on the sensed temperature, operating the fan at a second speed less than or greater than the first speed. The method can also include processing the sensed temperature with a temperature control band, and the operating the fan can be performed based on the processing of the sensed temperature.

To perform the method, the fan can be an axial fan, and a center axis of the axial fan can be perpendicular to the outer surface and coincide with a center of the chamber lid. The flow of the cooling air may then be directed into a center space among four showerheads mounted on the chamber lid. In these examples of the method, the center space can include a heat sink on the chamber lid, and the flow of the cooling air can be directed through a plurality of fins of the heat sink. The flow of the cooling air can also be directed to flow from the center space through gaps between adjacent pairs of the four showerheads.

According to further aspects of the description, a reactor system is provided that is adapted for cooling a chamber lid of a quad chamber module. The system includes the chamber lid and four showerheads each with a body with a sidewall extending from an outer surface of the chamber lid. The system includes a fan operable to provide a flow of air transverse to the chamber lid and onto the outer surface within a center space located centrally among the four showerheads.

The system may further include a fan housing enclosing the fan and the center space, and the flow of air can be directed from the center space to gaps between the sidewalls of adjacent pairs of the four showerheads. The system may further include a finned heat sink on the outer surface of the lid within the center space. In some examples of this system, a controller is included that is configured to generate control signals to operate the fan at a first speed and at a second speed higher than the first speed to provide first and second amounts of cooling of the chamber lid with the flow of air. The system may also include a temperature sensor adapted to sense a temperature of the chamber lid, and the controller may operate to generate the control signals to switch between the first and second speeds based on the sensed temperature of the lid. In some implementations of the system, the controller generates the control signals to switch between the first and second speeds based on a change in processes performed in the quad chamber module.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a functional block diagram of a reactor system that includes a cooling system of the present description operable to remove heat from a reaction chamber lid via controlled air flow.

FIG. 2 illustrates a top perspective view of a portion of a dual chamber module showing details of the module's lid and associated cooling system according to the present description such as for use in implementing the reactor system of FIG. 1.

FIG. 3 is sectional view of the module lid of FIG. 2 showing further details of the lid cooling system.

FIG. 4 is a simplified top view of the module lid of FIG. 2 with the fan assembly, the support brackets, and the heat sink removed showing air flow into and through the center space and gaps/passageways between adjacent showerheads.

FIG. 5 is a detailed view of the module lid of FIG. 4 after the addition of the finned heat sink into the center space.

FIG. 6 is flow diagram of a lid cooling method of the present description such as may be carried out by operation of the systems of FIGS. 1 and 2.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the terms “wafer” and “substrate” may be used interchangeably to refer to any underlying material or materials that may be used, or upon which, a device, a circuit, or a film may be formed.

As used herein, the term “chemical vapor deposition” (CVD) may refer to any process wherein a substrate is exposed to one or more volatile precursors, which react and/or decompose on a substrate surface to produce a desired deposition.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As described in greater detail below, various details and embodiments of the disclosure may be utilized in conjunction with a reaction chamber configured for a multitude of deposition processes, including but not limited to, ALD, CVD, metalorganic chemical vapor deposition (MOCVD), and MBE, and physical vapor deposition (PVD). The embodiments of the disclosure may also be utilized in semiconductor processing systems configured for processing a substrate with a reactive precursor, which may also include etch processes, such as, for example, reactive ion etching (RIE), capacitively coupled plasma etching (CCP), and electron cyclotron resonance etching (ECR).

Reactor systems that include reactor modules with two or more reaction chambers contained within a single reaction housing or vessel can have issues with non-uniform temperature in the reaction chamber lid, which can create issues with wafer processing. Particularly, a hot spot can arise at the center portion of the chamber lid, which can result in undesired heat being reflected to one or more of the reaction chambers and possible non-uniformity of temperatures on a processed wafer. To control or even eliminate this hot spot and provide a more uniform lid temperature profile, a cooling system was designed that uses convective heat transfer to draw heat away from the center of the chamber lid and provide cooling of other areas such as spaces between showerheads.

In brief, a reactor system is described for use in semiconductor processing, such as for chemical vapor deposition (CVD), atomic layer deposition (ALD), and other deposition or etch steps, that makes use of a reactor module with two to four or more reaction chambers. The reactor system includes components of a cooling system to provide enhanced temperature uniformity across a chamber lid enclosing the housing or vessel containing the reaction chambers. In part, the cooling system is adapted to utilize convective heat transfer and includes a finned heat sink positioned at the center of the chamber lid in the center space between the external portions of the showerheads of the reaction chambers. Further, the lid cooling system includes a fan positioned to have its outlet at the center space and over the finned heat sink so that air out of (or cooling air) is directed into the center space and onto the heat sink.

The air from the cooling system is directed to flow outward from the center space to gaps or passageways between adjacent pairs of showerheads (or portions of their bodies extending outward from the exterior or outer surface of the chamber lid). Additional chamber module hardware such as support or mounting brackets may be used to retain the flowing air within the gaps or passageways between the showerheads. In this manner, an air flowing channel is defined in which convective heat transfer from the lid may occur to provide a more uniform temperature profile for the lid by cooling the center hot spot of the lid, and this channel is defined by a combination of the fan housing, the outer surface of the lid, the outer surfaces of the showerhead bodies extending up from the lid outer surface, and additional module hardware positioned over the gaps/passageways between the showerhead bodies.

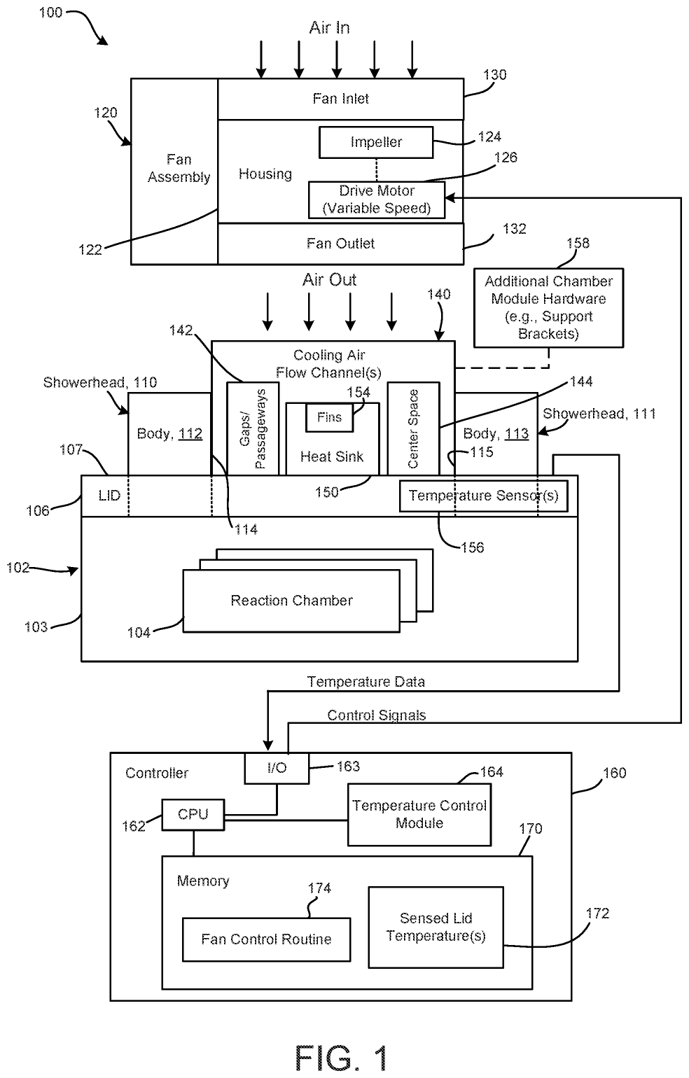

FIG. 1 is a functional block diagram of a reactor system 100 that includes a cooling system of the present description operable to remove heat from a reaction chamber lid 106 via controlled air flow. In general, the cooling system may include a fan assembly 120, an air flow channel or cooling plenum 140, a finned heat sink 150 provided on the center portion of the chamber lid 106 within the air flow channel 140, a temperature sensor(s) 156 monitoring temperatures of the lid 106, and a controller 160 running software to provide the functions of a temperature control module 164, including issuing control signals 161 to the drive motor 126 (or its driver) of the fan assembly 120 to control air flow into that air flow channel 140 (shown with arrows labeled Air_{Out}). While air is a common cooling fluid for use with fan assembly 120, other cooling gases may be utilized to implement the system 100.

As shown in FIG. 1, the reactor system 100 includes a reactor module 102 with a vessel or housing 103 defining an interior space adapted to contain two or more reaction chambers 104 (e.g., two chambers 104 may be provided to achieve a dual chamber module 102, four chambers 104 may be provided to achieve a quad chamber module 102, and so on). A lid 106 is provided to enclose the upper portion of the chamber housing 103, and two or more showerheads 110, 111 (or other processing material deposition components) are mounted upon the lid 106 with a portion of the showerhead extending outward from the lid 106. Typically, there may be one showerhead 110, 111 per reaction chamber 104.

Each of the showerheads 110, 111 includes a body 112, 113 with an outer surface or sidewall 114, 115 extending above an outer or exterior surface 107 of the lid 106. Typically, there is a small gap or passageway 142 between adjacent pairs of the showerheads 110, 111 such as with the outer surfaces or sidewalls 114, 115 being spaced apart 1 to 10 millimeters (mm) or the like. Further, in some systems 100 such as ones with a quad chamber module 102, a center space 144 that is above a center point or portion of the lid 106 is defined by interior corner portions of the outer surfaces or sidewalls 114, 115 of all the showerhead bodies 112, 113, and this center space 144 may be generally square in cross sectional shape with a height measured from the lid surface 107 to a height of each showerhead outer wall or surface 114, 115.

This center space 144 opens up to each of the gaps or passageways 142, such that the gaps 142 when combined with the center space 144, at least in part, define the air flow channel 140. Further, the system 100 may include additional chamber module hardware 158, such as support or mounting brackets or shields for the bodies 112, 113, that may further define the channel 140, such as by capping or covering the gaps/passageways 142, such that air is blocked or partially blocked from flowing upward or perpendicular to the lid surface 107 and, instead, is forced to flow radially outward through the gaps/passageways 142 from the center space 144.

The cooling system may comprise the fan assembly 120 that is operable to draw air in, Air_{In}, and exhaust or output air out, Air_{Out}, into the air flow channel 140 to cool the lid 106 by flowing this output air, Air_{Out}, over the lid's upper surface 107 and heat sink 150. The fan assembly 120 includes the fan housing 122 that defines the fan's inlet 130 and outlet 132, which is positioned relative to the lid 106 to direct the output air, Air_{Out}, into the center space 144 between corner portions of the bodies 112, 113 (e.g., between four showerheads in a quad chamber module 102 embodiment).

Particularly, the housing 122 contains the fan's impeller/blades 124 and the drive motor 126 that is operable to rotate the impeller 124 to draw in air, Air_{In}, and output air, Air_{Out}, and the center axis of the impeller 124 may coincide with a center point of the lid 106. To limit loss of the output air, Air_{Out}, the housing 122 may be configured to mate at the fan outlet 132 with a sidewall or outer surface 114, 115 of the bodies 112, 113 of the showerheads 110, 111 (or with a shield or cap if one is provided over the bodies 112, 113) to direct the output air, Air_{Out}, into the center space 144. The fan impeller 124 and motor 126 may be selected to provide a desired flow rate such as in the range of 500 to 1500 m³/h, 790 to 1220 m³/h, or the like, to achieve a desired amount of cooling of the lid 106. In some embodiments, it may be desirable for the drive motor 126 to be a variable speed motor to control the output air, Air_{Out}, to be a value within its design capacity range, such as speeds ranging from 1000 up to 6500 RPM or more, with higher speeds used to provide greater air flow rates and greater cooling and with varying speed being responsive to control signals 161 from the system controller 160. In some cases, a direct current (DC) axial fan is utilized for the fan assembly 120, such as one with a 790 m3/h air flow capacity or the like, one with variable speed controls between 1000 and 4250 RPM, and with a central axis coinciding with a center point of the lid 106 and center axis of the center space 144.

A heat sink 150 is positioned within the center space 144 such that the output air, Air_{Out}, of the fan assembly 120 initially cools the heat sink 150, and it may comprise a plurality of heat transfer fins 154 extending outward from its body and through which the air will flow to enhance convective heat transfer. The body of the heat sink 150 may be formed of a metal, such as aluminum, steel, or the like, and be mated with the upper surface 107 of the lid 106 or may be formed integrally with the lid 106 (e.g., the heat sink 150 and its fins may be machined into the center of the lid 106). The body or just the fins 154 may extend outward from the surface 107, such as upward from surface 107 a distance of 10 to 50 mm or more.

The cooling system may further comprise a controller 160, which may take the form of nearly any type of electronic or computing device. For example, the controller 160 may comprise a processor 162 that manages operations of input/output (I/O) devices 163 to communicate with a temperature sensor(s) 156 on the lid 106 in a wired or wireless manner to receive temperature data/signals 157 from the sensor 156. The I/O devices 163 may also be used to communicate control signals 161 to the drive motor 126 of the fan assembly 120, such as to vary the speed of the motor 126 based on the temperature of the lid 106 sensed by the sensor 156.

The processor 162 may also execute code, instructions, and/or software to provide the functions of a temperature control module 164, which include processing the temperature data 163 to store sensed lid temperatures 172 in local or remote memory 170 and, in response, to generate control signals 161 to set the speed of the drive motor 126. The control module 164 may run a fan control routine 174 to provide desired amounts of output air, Air_{Out}, during operations of the system 100, and this may involve setting the drive motor at one or more speeds during particular processing operations such as based on known amounts of desired cooling for these processes. In other cases, the routine 174 may call for a default fan speed that can then be modified to provide less or more air flow in response to sensed lid temperatures 164 from sensor(s) 156, e.g., by calling for decreased speed when temperatures fall below a lower limit of a control band and for increased speed when temperatures rise above a higher limit of a control band.

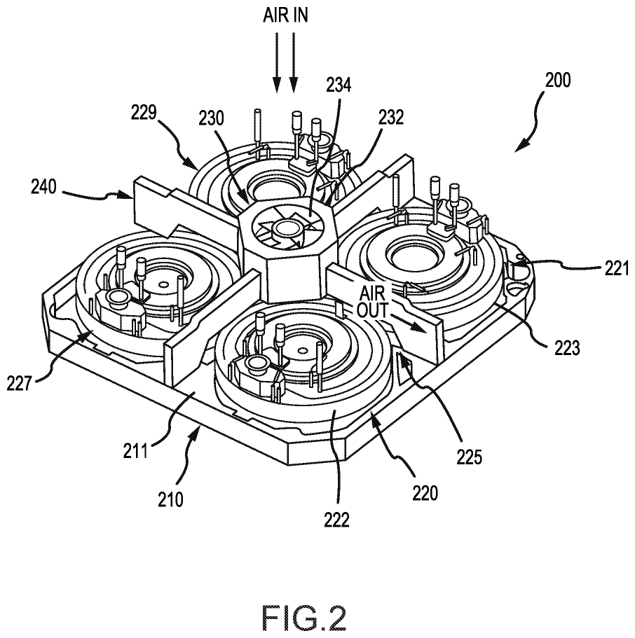

FIG. 2 illustrates a top perspective view of a portion of a quad chamber module 200 showing details of the module's lid 210 and an associated cooling system according to the present description such as for use in implementing the reactor system 100 of FIG. 1. As shown, the module 200 is a quad chamber module, and the lid 210 is configured with four openings to four reaction chambers (not shown but understood with reference to FIG. 1 and chambers 104). The lid 210 has an outer or exterior surface 211 facing upward or away from the reaction chambers below the lid 210.

The module 200 further includes four showerheads 220, 221, 227, 229 mounted on the surface 211 of the lid 210, with showerheads 220, 221 illustrating an adjacent pair of these four showerheads. As shown, the outer surfaces or sidewalls 222, 223 of these are positioned very close together with a small gap or passageway 225 defined between the showerheads 220, 221 (or the portion of their bodies extending above the surface 211 of the lid 210). During operations of the module 200 as discussed below, output air, Air_{Out}, is forced to flow through this small (e.g., 1 to 10 mm wide) gap 225.

The air flow channel between the adjacent pair of showerheads 220, 221 is further defined by additional module hardware that is positioned above the gap 225 to fully or at least partially cap or enclose the gap 225. In the example module 200 of FIG. 2, a set of four support or mounting brackets 240 are positioned between adjacent pairs of showerheads such as showerheads 220, 221, and one of the bodies of each of the brackets 240 extends from the center space between the four showerheads to an outer edge of the lid 210, with an opening provided at the outer end to provide an outlet for the output air, Air_{Out}. To this end, the body of the brackets 240 may have a raised portion or cutout with a height of about that of the outer surfaces or sidewalls 222, 223 of the showerheads 220, 221, such that the air flow channel through the gap 225 has a height as measured from the lid upper surface 211 to the bottom of the bracket 240 above the gap in the range of 30 to 100 mm with 40 to 60 mm being useful in some cases. In some cases, the height of the flow channel in the gaps 225 is about a height of the cooling fins of the heat sink in the center space, which is discussed below and is about 50 mm in one implementation of the module 200.

The cooling system for module 200 may further comprise a fan assembly 230 that is centrally located relative to the lid 210. The fan assembly 230 may comprise a housing 232 that contains a drive motor and impeller/fan blades as discussed with reference to FIG. 1, and the housing 232 includes a fan inlet 234 through which air is drawn in during operations of the fan assembly 230 (e.g., operations of a DC or other motor at a particular speed within a range of motor speeds to achieve a desired flow rate of air over the lid surface 211 including Air_{Out}). The air is forced into the center space between the four corners of the showerheads 220, 221, 227, 229 against the lid surface 211 and through the gaps 225 between adjacent pairs of showerheads (as shown with showerheads 220, 221). The housing 232 has sidewalls, e.g., sheet metal or the like) that encloses the center space and forces the intake or input air, Air_{In}, to flow through the gaps 225, and, to this end, bottom edges of the housing 232 can abut or mate with an upper surface of the body of the showerheads 220, 221 and/or with an upper portion of the outer surface or sidewalls 222, 223 of the showerheads 220, 221. A center axis of the fan housing 232 may coincide with a center point of the lid 210 or its exterior or outer surface 211 in some implementations.

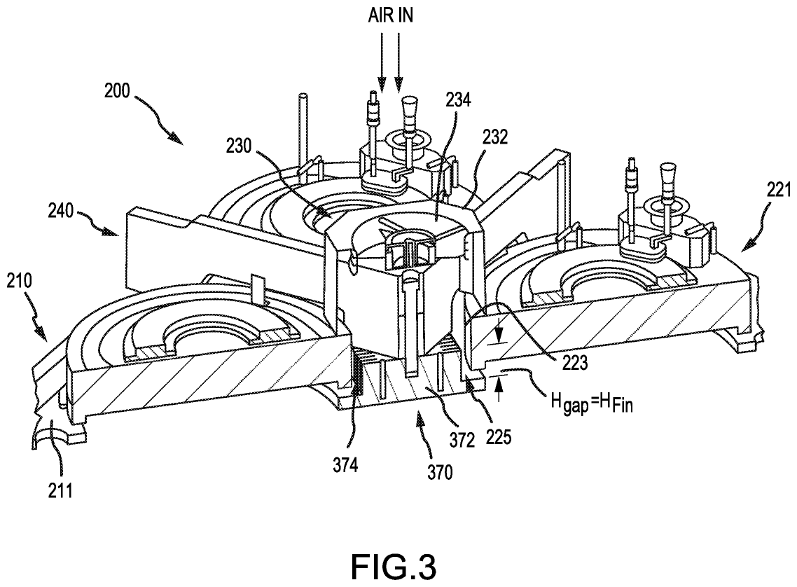

FIG. 3 is sectional view of the module lid 210 of FIG. 2 showing further details of the cooling system. As shown, the lower edges of the fan housing 232 abuts an upper surface of the body of the showerheads 220, 221 as well as mating with exterior surfaces of the brackets 240, and this arrangement encloses a center space between the four showerheads in combination with the lid outer surface 211. FIG. 3 also shows an inlet from this center space to the gap/passageway 225 between showerheads 220, 221, which receives a portion (e.g., about one fourth) of the cooling air output from the fan assembly 230.

As shown in FIG. 3, the cooling system further includes a heat sink 370 positioned in the center space and with its center axis coinciding with the center of the lid 210 (and with the center axis of fan housing 230). The heat sink 370 is shown to be integrally formed with the lid 210, such as by machining or other processes, but other embodiments may utilize a heat sink that is fabricated separately and attached to the upper surface 211 in the center space. The heat sink 370 includes a body 372 (e.g., a portion of the lid 210), and a plurality of heat exchange fins 374 extend upward a distance (e.g., 10 to 50 mm or more) from the upper surface of the body 372 (which may coincide with the outer surface 211 as shown in FIG. 3). This distance defines a height, H_{Fin}, of the fins 374, which may match the height, H_{Gap}, of the gap or passageway 225, such as when the end of the bracket 240 rest on the fins 374 as shown in FIG. 3.

The number and arrangement of the fins 374 may vary to achieve a desired amount convective heat transfer between the heat sink 370 and material of the interconnected lid 210 at the center of the lid 210 where hot spots can occur. In one embodiment, the fins 374 are provided in four sets of 10 to 30 or more spaced apart fins, each with a width of 2 to 20 mm, and the sets are arranged about the periphery of the heat sink body 372. Air output from the fan assembly 230 may flow through the fins 374 prior to entering the passageways 225 between showerheads 220, 221 or the fins 374 may be positioned to provide a more direct pathway for at least a portion of the air output from the fan assembly 230.

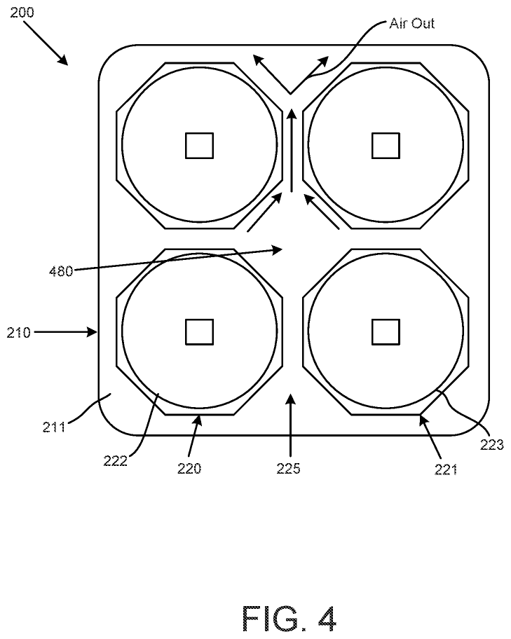

FIG. 4 is a simplified top view of the module lid 200 of FIG. 2 with the fan assembly 230, the support brackets 240, and the heat sink 370 removed showing air flow with arrows, Air_{Out}, into and through the center space 480 and gaps/passageways 225 between adjacent showerheads 220, 223. As shown, the center space 480 is defined by the sidewalls or outer surfaces 222, 223 of the bodies of the four showerheads 220, 221, 227, 229 where they face each other and are spaced apart at the center of the lid 210. FIG. 4 also is useful for showing that the gaps/passageways 225 between adjacent pairs of the showerheads, such as showerheads 220, 221, can be relatively small, such as 2 mm in some cases, such that forced convection is desirable to push the output air, Air_{Out}, across the lid surface 211 in these locations where air flow would not naturally occur at a useful rate for cooling.

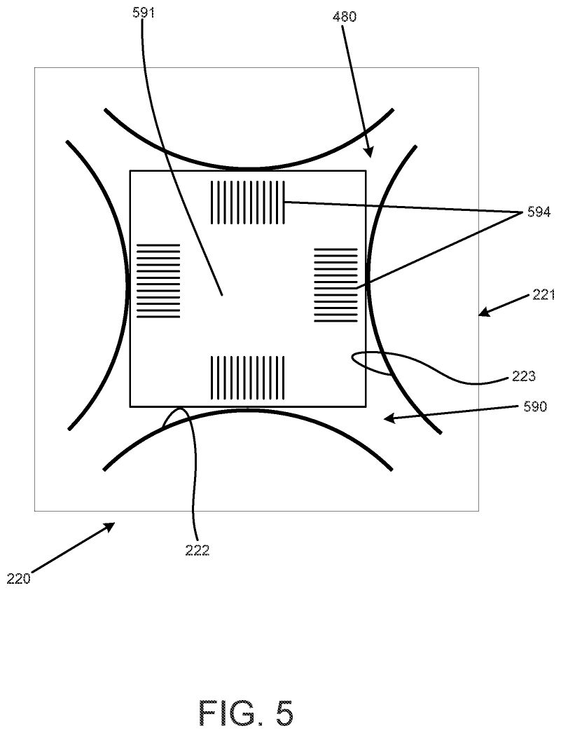

FIG. 5 is a detailed view of a center portion of the module lid of FIG. 4 after the addition of a finned heat sink 590 into the center space 480. As discussed above, the heat sink 590 may be integrally formed within the lid 210 by machining the surface 211 or it may be formed separately and later attached to facilitate conductive heat transfer between the body of the heat sink 590 and the material of the lid 210. The heat sink 590 may comprise four sets of fins 594 spaced apart and positioned proximate to outer surfaces 222, 223 of the showerheads 220, 221, which provides an unobstructed path for a portion of the output air, Air_{Out}, to flow into the four gaps/passageways 225.

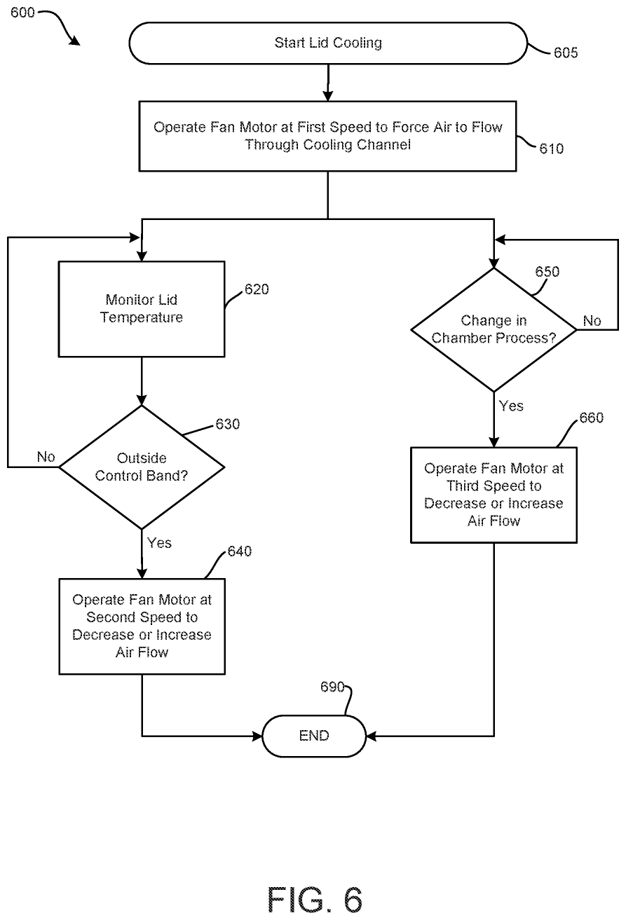

FIG. 6 is flow diagram of a cooling method 600 of the present description such as may be carried out by operation of the systems 100 and 200 of FIGS. 1 and 2. The method 600 starts at 605 that can include installing a cooling system upon a dual or quad chamber module lid (e.g., lid 106, 210) including providing one or more finned heat sinks (such as within a center space among showerheads as with heatsink 150) and mounting a fan (e.g., fan 120, 230) with its housing (e.g., housing 122, 232) above the heat sinks (such as to enclose the center space with the sidewalls of the housing). Step 605 may also include providing a controller (e.g., controller 160 for the fan assembly's drive motor (e.g., motor 126) and programming (e.g., with fan control routine 173) the controller to generate control signals to vary the fan motor speed at one or more points in operation of a reactor system (e.g., system 100) that includes the chamber module and its cooling components.

The method 600 continues with step 610 that involves operating the fan motor at a first speed to force air flow at a first rate through the cooling channel (e.g., channels 140, 225). As noted above, the cooling channel is defined by the fan housing, the lid's outer or exterior surface (e.g., surface 107), the outer surfaces or sidewalls (e.g., surface or walls 114, 115, 222, 223) of the bodies of the showerheads (extending above the lid surface), and any additional module hardware, such as brackets (e.g., brackets 158, 240), that may enclose or cap that center space (e.g., space 144) and/or the gaps/passageways (e.g. gaps 142, 225) between showerheads. In some embodiments, one or more finned heat sinks (e.g., heat sink 150) are provided in the cooling channel to facilitate heat extraction from the lid's outer surface.

The method 600 at step 620 involves monitoring the lid temperature, such as with one or more temperature sensors positioned on the lid outer surface that may be positioned at the center of the lid, at the four outlets of the gaps/passageways of the cooling channel, or other useful positions on the lid surface. At step 630, the controller of the cooling system may compare the sensed temperature(s) from step 620 to a temperature control band to determine, such as based on a control algorithm, whether or not to change the fan motor speed based on the sensed temperature. For example, low and high temperature limits may be set for adjusting speed from the first speed set at step 610. If the sensed temperature is not outside the control band or not above or below these limits, the method 600 may continue at step 620.

If, based on the comparison at step 630, the controller determines that a different amount of air flow is desirable, the method 600 continues at step 640 with the controller generating control signals to operate the fan motor at a second speed that is lower than the first speed to provide a lower flow rate and less cooling of the lid (especially its center portion) or that is higher than the first speed to provide a greater flow rate and more cooling of the lid. The method 600 may then continue at step 620 with additional temperature monitoring or may end at step 690.

Additionally or as an alternative to step 620, the method 600 may continue after step 610 with step 650 that involves the controller monitoring the processes occurring within the reaction chambers. The first speed of the motor set at step 610 may be set for initial reaction chamber operations/processes, and, if these are not changed as determined at step 650, the method 600 may continue at 650 with the first speed being maintained for the fan motor (and same cooling air flow through the cooling channel).

If the chamber processes are determined at step 650 to have changed to new processes that are associated with a reduced or increased need for lid cooling, the method 600 continues at step 660 with the controller generating control signals to operate the fan motor at a third speed associated with the new processes. The third speed may be lower than the first speed when less cooling is desired or may be higher than the first speed when more cooling of the lid is desirable (e.g., when higher temperature processes are being initiated in one or more of the reaction chambers). The method 600 may then continue at 650 with additional process monitoring or may end at step 690 (such as when the reaction chambers become idle).

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A reactor system adapted for forced convection cooling of a multi-chamber module, comprising:
a lid for the multi-chamber module;
a set of showerheads supported on the lid, wherein each of the showerheads includes a body with a sidewall extending a distance outward from an outer surface of the lid;
a cooling channel comprising gaps between the sidewalls of adjacent pairs of the showerheads; and
a fan assembly with a fan housing enclosing an impeller and a motor and defining a fan inlet and a fan outlet, wherein, when the motor is operating, cooling air is drawn into the fan inlet from a space exterior to the lid and forced out of the fan outlet into the cooling channel to flow through the gaps.

2. The system of claim 1, wherein the set of showerheads comprises four showerheads, wherein the cooling channel further comprises a center space enclosed by the fan housing, a center portion of the outer surface of the lid, and adjacent portions of the sidewalls of the bodies of the four showerheads, and wherein the fan outlet is configured to direct the cooling air forced out of the fan outlet into the center space.

3. The system of claim 2, further comprising a heat sink positioned within the center space and integrally formed with the lid or in contact with the outer surface of the lid, wherein the heat sink includes a plurality of fins extending outward away from the lid.

4. The system of claim 2, wherein the fan assembly has a center axis that coincides with a center of the center space and a center of the lid.

5. The system of claim 1, further comprising a set of module hardware extending over and at least partially enclosing the gaps, whereby the cooling air is directed to flow between adjacent pairs of the showerheads.

6. The system of claim 1, wherein the motor is a variable speed motor operable over a range of speeds and wherein the system further comprises a controller configured to generate control signals to operate the motor at a first speed and at a second speed higher than the first speed.

7. The system of claim 6, further comprising a temperature sensor adapted to sense a temperature of the lid and wherein the controller generates the control signals to switch between the first and second speeds based on the sensed temperature of the lid.

8. The system of claim 6, wherein the controller generates the control signals to switch between the first and second speeds based on a change in processes performed in the multi-chamber module.

9. A method of controlling a chamber lid temperature in a reactor system, comprising:
operating a fan at a first speed to direct a flow of cooling air onto an outer surface of the chamber lid;
sensing a temperature of the chamber lid; and
based on the sensed temperature, operating the fan at a second speed less than or greater than the first speed.

10. The method of claim 9, further comprising processing the sensed temperature with a temperature control band and wherein the operating the fan is performed based on the processing of the sensed temperature.

11. The method of claim 9, wherein the fan is an axial fan and wherein a center axis of the axial fan is perpendicular to the outer surface and coincides with a center of the chamber lid.

12. The method of claim 9, wherein the flow of the cooling air is directed into a center space among four showerheads mounted on the chamber lid.

13. The method of claim 12, wherein the center space includes a heat sink on the chamber lid and wherein the flow of the cooling air is directed through a plurality of fins of the heat sink.

14. The method of claim 12, wherein the flow of the cooling air is directed to flow from the center space through gaps between adjacent pairs of the four showerheads.

15. A reactor system adapted for cooling a chamber lid of a quad chamber module, comprising:
the chamber lid;
four showerheads each with a body with a sidewall extending from an outer surface of the chamber lid; and
a fan operable to provide a flow of air transverse to the chamber lid and onto the outer surface within a center space located centrally among the four showerheads.

16. The system of claim 15, further including a fan housing enclosing the fan and the center space, wherein the flow of air is directed from the center space to gaps between the sidewalls of adjacent pairs of the four showerheads.

17. The system of claim 15, further comprising a finned heat sink on the outer surface of the lid within the center space.

18. The system of claim 15, further comprising a controller configured to generate control signals to operate the fan at a first speed and at a second speed higher than the first speed to provide first and second amounts of cooling of the chamber lid with the flow of air.

19. The system of claim 18, further comprising a temperature sensor adapted to sense a temperature of the chamber lid and wherein the controller generates the control signals to switch between the first and second speeds based on the sensed temperature of the lid.

20. The system of claim 18, wherein the controller generates the control signals to switch between the first and second speeds based on a change in processes performed in the quad chamber module.
